(19) United States
(12) Patent Application Publication
(10) Pub. No.: US 2024/0349457 A1
(43) Pub. Date: Oct. 17, 2024

(54) DAMPING ASSEMBLIES FOR HEAT SINKS AND RELATED METHODS

(71) Applicants: Phil Geng, Washougal, WA (US); David Shia, Portland, OR (US); Donald Tiendung Tran, Phoenix, AZ (US); James Trevor Goulding, Sherwood, OR (US); Jeffory L. Smalley, Olympia, WA (US); Ralph V. Miele, Hillsboro, OR (US); Sanjoy Kumar Saha, Portland, OR (US); Jing-Hua He, Portland, OR (US); Steven Adam Klein, Chandler, AZ (US); Ethan Russell Long, Beaverton, OR (US); Andres Ramirez Macias, Zapopan (MX); Irving Joseph Castro Guzman, Tlajomulco de Zuñiga (MX)

(72) Inventors: Phil Geng, Washougal, WA (US); David Shia, Portland, OR (US); Donald Tiendung Tran, Phoenix, AZ (US); James Trevor Goulding, Sherwood, OR (US); Jeffory L. Smalley, Olympia, WA (US); Ralph V. Miele, Hillsboro, OR (US); Sanjoy Kumar Saha, Portland, OR (US); Jing-Hua He, Portland, OR (US); Steven Adam Klein, Chandler, AZ (US); Ethan Russell Long, Beaverton, OR (US); Andres Ramirez Macias, Zapopan (MX); Irving Joseph Castro Guzman, Tlajomulco de Zuñiga (MX)

(21) Appl. No.: 18/754,759

(22) Filed: Jun. 26, 2024

(51) Int. Cl. H05K 7/20

(52) U.S. Cl. CPC H05K 7/2039; H05K 7/20709

(57) ABSTRACT

Damping assemblies for heat sinks and related methods are disclosed. An example apparatus includes a chassis; a first heat sink associated with an electronic component in the chassis; a second heat sink coupled to the first heat sink, the second heat sink spaced apart from the first heat sink in the chassis; and damping material proximate to the second heat sink.

### BACKGROUND

A heat sink facilitates the transfer of heat away from a heat source such as an electronic component and into a medium such as air to regulate temperature of the electronic component. In a data center, the electronic component may be carried by a chassis that also houses other electronic components. The chassis may be stored on a rack in the data center with other chassis.

### BRIEF DESCRIPTION OF THE DRAWINGS

FIG. 1 illustrates a known chassis including electronic components, a first heat sink, and a second heat sink.

FIG. 2 is a schematic side view of an example chassis constructed in accordance with teachings of this disclosure and including one or more dampers for a second heat sink.

FIGS. 3A-3F illustrate example arrangements of damper(s) for the second heat sink of FIG. 2.

FIG. 4 is a schematic top view of the example chassis of FIG. 2.

FIG. 5 illustrates an example damper that may be used with the second heat sink of FIG. 2 in accordance with teachings of this disclosure.

FIGS. 6-9 illustrate example support assemblies for the second heat sink of FIG. 2 in accordance with teachings of this disclosure.

FIG. 10 illustrates an example land grid array assembly including a heat sink.

FIG. 11 is a schematic illustration of a heat sink assembly of the example land grid array assembly of FIG. 10.

FIG. 12 is a schematic illustration of the example land grid array assembly of FIG. 10 including damper(s) coupled to a carrier of the example heat sink assembly of FIG. 11 in accordance with teachings of this disclosure.

FIGS. 13 and 14 illustrate the carrier of the example heat sink assembly of FIG. 12 including the damper(s).

FIG. 15 is a partial cross-sectional view of the example land grid assembly of FIG. 12.

FIGS. 16 and 17 illustrate example carriers including damper(s) in accordance with teachings of this disclosure.

FIG. 18 is another schematic illustration of the example land grid array assembly of FIG. 10 including damper(s) coupled to the carrier of the example heat sink assembly of FIG. 11 in accordance with teachings of this disclosure.

FIGS. 19A-19F illustrate example carriers including damper(s) in accordance with teachings of this disclosure.

FIGS. 20 and 21 illustrate an example heat sink including damper(s) coupled thereto in accordance with teachings of this disclosure.

FIGS. 22 and 23 illustrate example land grid array assemblies including damper(s) in accordance with teachings of this disclosure.

FIGS. 24-27 are flowcharts of example methods for providing damping at heat sinks in accordance with teachings of this disclosure.

In general, the same reference numbers will be used throughout the drawing(s) and accompanying written description to refer to the same or like parts. The figures are not necessarily to scale. Instead, the thickness of the layers or regions may be enlarged in the drawings.

### DETAILED DESCRIPTION

A heat sink facilitates the transfer of heat away from a heat source such as an electronic component and into a medium such as air to regulate temperature of the electronic component. The electronic component and the heat sink may be carried by a chassis that also houses other electronic components. The chassis may be stored on a rack in a data center with other chassis. The chassis may have a height corresponding to one rack unit in height (i.e., a “1U” chassis).

The heat sink sits over the electronic component in the chassis to facilitate the transfer of heat from the electronic component via a thermal interface between the electronic component and the heat sink. The chassis can include a second heat sink to provide for additional cooling of one or more electronic components in the chassis in view of operation of the heat-generating electronic component(s). However, because of the height limitations of a 1U chassis, the second heat sink may be spaced apart from the first heat sink in the chassis rather than stacked on the first heat sink. Thus, the second heat sink can be considered a remote heat sink relative to the first heat sink and the electronic component(s) associated with the first heat sink. The first heat sink and the second heat sink can be coupled via heat pipes that extend between the heat sinks.

The heat sink(s) may be exposed to vibration and/or shock forces during transport of the chassis, installation in the rack, operation of the electronic components, etc. The remote heat sink may be heavier than the first heat sink (i.e., the heat sink that sits over the electronic component) to provide additional cooling capabilities. However, under shock and vibration loads experienced by the chassis, the heavier remote heat sink can cause rocking or lateral movement of the first heat sink. As a result, the electronic component associated with the first heat sink may move. The electronic component can include a semiconductor chip package. Due to rocking or lateral movement of the first heat sink, the semiconductor chip package may move laterally relative to a socket to which the semiconductor chip package is electrically coupled. Such movement of the semiconductor chip package can cause scratching, cracking, or skiving of walls of the socket and/or introduce instabilities with respect to electronical connections between the semiconductor chip package and pins of the socket.

Although rigidly coupling the remote heat skink to the chassis can reduce effects of shocks and vibrations at the remote heat sink, such rigid coupling can contribute to lateral shifting and misalignment between the semiconductor chip package and its corresponding socket due to tolerance issues. Misalignment between the semiconductor chip package (e.g., a pad of the semiconductor chip package) and the socket pins can result in electrical discontinuity or signal integrity issues.

To provide for tolerance between the electronic components of the chassis, the remote heat sink may sit or float (i.e., free from attachment) within a portion of the chassis. In some instances, strips of foam may be disposed on edges of the remote heat sink to prevent metal of the remote heat sink from scratching the chassis. However, such materials are not intended to provide for damping with respect to vibrations transferred from the chassis wall to the remote heat sink.

Disclosed herein are example damping assemblies for heat sinks to mitigate, substantially reduce, or prevent the effects of vibrations on one or more heat sinks in a chassis and, thus, the effects of vibrations on electronic components with which the heat sinks are associated in the chassis. Examples disclosed herein provide for damping in one or more directions (e.g., along x, y, and/or z-axis) via flexible placement of damper(s) relative to, for example, a remote heat sink. Examples disclosed herein provide for damping while allowing the remote heat sink to float or moveably sit on the chassis, thereby providing for damping while providing for tolerance with respect to other components in the chassis (e.g., the semiconductor chip package, the socket that receives the package, etc.). Some examples disclosed herein provide for damping of the heat sink that sits over the electronic components, where the damper(s) are carried by, for example, the heat sink, a carrier that supports a semiconductor chip package, etc. Examples disclosed herein enable the damper(s) to be placed at location(s) where the risks of cracking of the socket, fretting of the socket pins, etc. are increased to provide for targeted vibration mitigation. In examples disclosed herein, the damper(s) can be supported by, for example, the walls of the chassis, hardware such as the semiconductor chip package carrier, etc. to prevent shifting of the damper(s) over time.

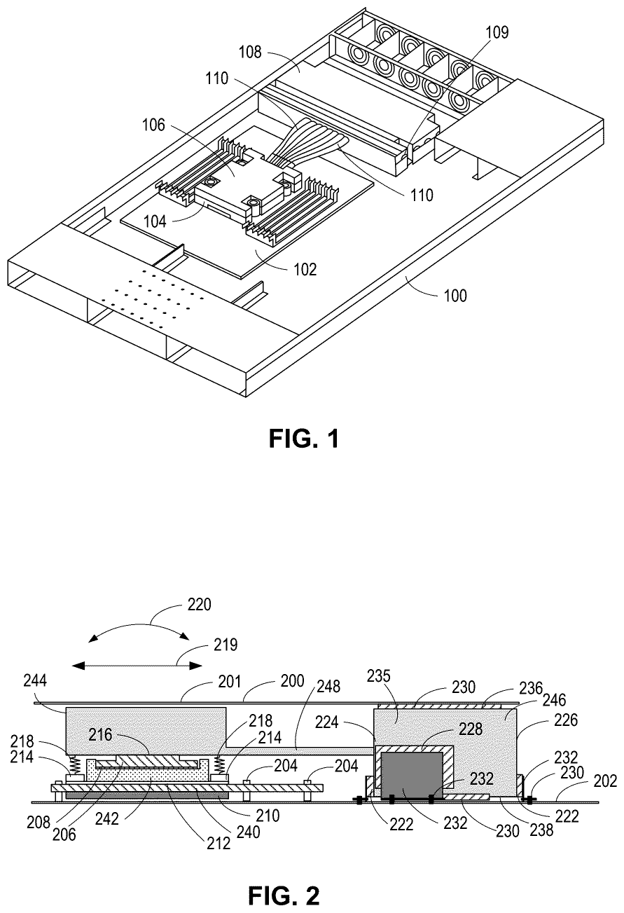

FIG. 1 illustrates a chassis 100 that houses electronic component(s), one or more of which are carried by a printed circuit board (PCB) 102. For illustrative purposes, a portion (e.g., a lid) of the chassis 100 has been removed to show an interior of the chassis 100. In FIG. 1, the electronic component(s) include a semiconductor chip package. The semiconductor chip package, which can include integrated circuit(s), is electrically coupled to a land grid array (LGA) socket 104. The LGA socket 104 is electrically coupled to the PCB 102. The PCB 102 can include other types of chip mounting packaging. Also, the PCB 102 can include other include other electronic component(s) (e.g., memory devices) coupled thereto.

In the orientation of the chassis shown in FIG. 1, a first heat sink 106 is located over the semiconductor chip package that is coupled to the LGA socket 104 to facilitate dissipation of heat generated by the semiconductor chip (e.g., an integrated circuit). Heat from the semiconductor chip is transferred to the first heat sink 106 via contact between the semiconductor chip package and a thermal interface material located between the semiconductor chip package and the first heat sink 106. The heat is absorbed by a medium such as air flowing through fins of the first heat sink 106.

To provide for additional temperature regulation of the semiconductor chip, the chassis 100 includes a second heat sink 108. The chassis 100 of FIG. 1 has a size corresponding to one rack unit in height (i.e., a “1U” chassis). Thus, because of the vertical (e.g., z-axis) height of the chassis 100 of FIG. 1, the second heat sink 108 may not be stacked on the first heat sink 106 without exceeding the height of the chassis 100. Accordingly, in FIG. 1, the second heat sink 108 is spaced apart from the first heat sink 106. The second heat sink 108 can sit in a pan 109 or other defined area of the chassis 100. Given the segregation of the second heat sink 108 from the first heat sink 106, the second heat sink 108 can be considered a remote or distal heat sink relative to the first heat sink 106. The second heat sink 108 is thermally coupled to the first heat sink 106 via one or more heat pipes 110 (e.g., copper pipes) extending between the first heat sink 106 and the second heat sink 108. Thus, heated air can travel from the first heat sink 106 to the second heat sink 108 via the heat pipe(s) 110 to provide for further dissipation of heat and cooling of the semiconductor chip. The medium (e.g., air) can be circulated back to the first heat sink 106 via the heat pipe(s) 110 after being cooled via the second heat sink 108.

FIG. 2 is a schematic side view of a portion of an example chassis 200246. The example chassis 200 of FIG. 2 carries a printed circuit board (PCB) 240, a land grid array (LGA) socket 242, a first heat sink 244, a second heat sink 246, and heat pipe(s) 248 that thermally couple the first heat sink 244 and the second heat sink 246. As disclosed herein, the example chassis 200 of FIG. 2 includes damper(s) for the second heat sink 246.

The chassis 200 of FIG. 2 includes a first surface, or lid, 201 and a second, opposing surface 202 (e.g., a bottom or base surface when the chassis 200 is in the orientation of FIG. 2). As shown in FIG. 2, the PCB 240 is coupled to the second surface 202 of the chassis 200 via, examples, fasteners 204 (e.g., screws, bolts). As also shown in FIG. 2, a semiconductor chip package 206 (also sometimes referred to herein as a LGA package 206) is at least partially received in the LGA socket 242 such that electrical connections are established between pins 208 of the LGA socket 242 and the semiconductor chip package 206 and, thus, between the semiconductor chip package 206 and the PCB 240 via the LGA socket 242.

In the example of FIG. 2, a back plate 210 is located between the second surface 202 of the chassis 200 and a side of the PCB 240 opposite the side that includes the LGA socket 242. A bolster plate 212 is located on the side of the PCB 240 including the LGA socket 242. As shown in FIG. 2, the bolster plate 212 frames or surrounds at least a portion of the LGA socket 242 (e.g., the LGA socket 242 sits in an opening of the bolster plate 212). Studs 214 extend from the back plate 210 through openings defined in the bolster plate 212 and the PCB 240 to couple the back plate 210, the PCB 240, and the bolster plate 212.

The first heat sink 244 facilitates the transfer of heat generated by the semiconductor chip package 206 to the first heat sink 244. For example, a base 216 of the first heat sink 244 can be in direct contact with at least a portion of the semiconductor chip package 206. In some examples, the base 216 of the first heat sink 244 includes a thermal interface material that engages the semiconductor chip package 206. In the example of FIG. 2, springs 218 are disposed between the base 216 of the first heat sink 244 and the bolster plate 212. For example, the springs 218 can be disposed between the first heat sink base 216 and the studs 214. The springs 218 regulate a load placed on the semiconductor chip package 206 and the LGA socket 242 by the first heat sink 244. Loads placed on the semiconductor chip package 206 and, thus, the LGA socket 242, by the first heat sink 244 can affect electrical couplings between the semiconductor chip package 206 and the LGA socket 242 and/or between the LGA socket 242 and the PCB 240. The springs 218 (e.g., loading mechanisms) can prevent over-loading or under-loading of the LGA package 206. Although the example of FIG. 2 includes the springs 218, other types of loading mechanisms could additionally or alternatively be used.

In the example of FIG. 2, the second or remote heat sink 246 is a floating heat sink. Put another way, the second heat sink 246 is not fixed immovably to the PCB 240 or the chassis 200. Rather, the second heat sink 246 can sit in, for example, an area of the chassis 200 (e.g., the pan 109 of FIG. 1) and, thus, is moveable laterally relative to the chassis 200. The second heat sink 246 is coupled to the first heat sink 244, which sits over the LGA package 206. The floating design of the second heat sink 246 reduces or prevents tolerance issues with respect to the LGA package 206 and the LGA socket 242 as compared to a design where the second heat sink 246 is rigidly coupled to the chassis 200 or the PCB 240. However, the second heat sink 246 may experience lateral shock loads or vibrational forces due to, for example, vibrations of the chassis walls during handling or shipping of the chassis 200, resonance due to operation of fan(s) in the chassis 200, etc. As result of the shock or vibration loads on the floating or moveable second heat sink 246, the second heat sink 246 can cause the first heat sink 244 to move laterally because of the coupling of the second heat sink 246 to the first heat sink 244 via the heat pipe(s) 248, as represented by arrow 219 in FIG. 2. For example, a mass of the second heat sink 246 may be greater than a mass of the first heat sink 244 and, thus, the second heat sink 246 can cause the first heat sink 244 to move. In some examples, under vibrational loads, the second heat sink 246 can cause the first heat sink 244 to rock (e.g., about the z-axis), as represented by arrow 220 in FIG. 2.

This movement of the first heat sink 244 places dynamic loads on the semiconductor chip package 206, which can cause lateral movement of the semiconductor chip package 206 within the LGA socket 242. As a result, the wall(s) of the LGA socket 242 can experience cracking or skiving due to interactions between the semiconductor chip package 206 and the wall(s) of the LGA socket 242. Further, rocking of the first heat sink 244 can cause fretting or scratching of metal portions of the semiconductor chip package 206 (e.g., a gold layer on a pad of the semiconductor chip package 206) due to, for example, friction between the pins 208 and the semiconductor chip package 206 as the semiconductor chip package 206 shifts laterally relative to the LGA socket 242. Also, the durability of the pins 208 and stability of the electrical connections provided by the pins 208 can be affected due to the lateral shifting of the semiconductor chip package 206. The effects of shocks and vibrations on movement of the first heat sink 244, the LGA package 206, the LGA socket 242, and/or the pins 208 increase as the mass of the second heat sink 246 increases. The first heat sink 244, the LGA package 206, the LGA socket 242, and the pins 208 are collectively sometimes referred to herein as an LGA stack or an LGA assembly).

In the example of FIG. 2, damper(s) 222, 228, 230 (e.g., shock absorbers) are disposed in the chassis 200 proximate to the second heat sink 246 to maintain the floating design of the second heat sink relative to the chassis 200 and the PCB 240 while reducing effects of shock and vibration forces on the LGA assembly (e.g., the first heat sink 244, the LGA package 206, the LGA socket 242, the pins 208) that could otherwise cause skiving or cracking of the LGA socket 242, pin fretting, etc. due to movement of the LGA package 206 within the LGA socket 242. The damper(s) 222, 228, 230 proximate to the second heat sink 246 mitigate vibrations and shocks experienced by the second heat sink 246. As a result, movement of the first heat sink 244 from the transfer of forces is substantially reduced or prevented. Consequently, movement of the LGA package 206 within the LGA socket 242 is substantially reduced or prevented, thereby preventing, for example, the LGA package 206 from hitting the wall(s) of the LGA socket 242 and cracking the wall(s).

The damper(s) 222, 228, 230 can be disposed in the chassis 200 along x, y, and/or z-axes to mitigate loads experienced by the second heat sink 246 in one or more directions. For example, as shown in FIG. 2, first damping material(s) 222 are disposed along an x-axis at first and second surfaces 224, 226 of the second heat sink 246. In this example, second damping material(s) 228 are disposed in the chassis 200 along the y-axis and extending along a third surface 235 of the second heat sink 246. Further, third damping material(s) 230 are disposed along the z-axis. As shown in FIG. 2, the third damping material(s) 230 are between a fourth surface 236 and the second heat sink 246 and the first surface 201 (e.g., lid) of the chassis 200 and between an opposing fifth surface 238 of the second heat sink 246 and the second surface 202 (e.g., bottom surface) of the chassis 200. Thus, multi-dimensional damping can be provided along two or more axes.

The damper(s) 222, 228, 230 can include materials such as silicone, rubber, or other materials selected based on, for example, thermal properties of the material. The damper(s) 222, 228, 230 can be supported in the chassis 200 via mechanical retainer(s) 232. The retainer(s) 232 can include mechanical fastener(s), support(s), mounts(s), etc. such as screw mounts. The retainer(s) 232 enable the damping material(s) 222, 228, 230 to maintain a fixed or substantially fixed position relative to the chassis 200 and prevent movement of the damper(s) 222, 228, 230 during any movement of the floating second heat sink 246. In some examples, the damping material(s) 222, 228, 230 may be chemically fastened to the chassis 200. In some examples, the damping material(s) 222, 228, 230 are secured via a friction fit between the second heat sink 246 and the chassis 200. The damper(s) 222, 228, 230 can have other shapes, sizes, etc. than shown in FIG. 2. Also, although in the example of FIG. 2, the damper(s) 222, 228, 230 are shown in the chassis 200 in the x, y, and z directions, in other examples, the damper(s) 222, 228, 230 may be in one or two of the directions. In some examples, the chassis 200 includes additional dampers or fewer dampers than shown in FIG. 2.

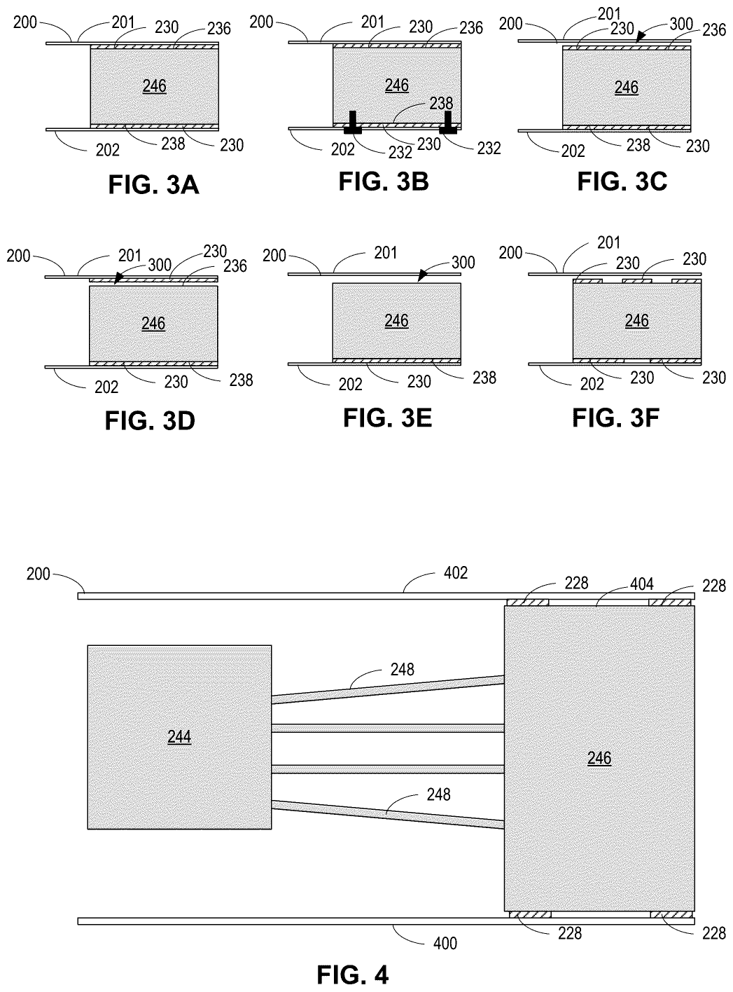

FIGS. 3A-3F show different example arrangements of the damper(s) 230 in the chassis 200 of FIG. 2 relative to the z-axis for mitigation of loads experienced by the second heat sink 246 in the z-direction. For illustrative purposes, the damper arrangements of FIGS. 3A-3F are shown in the z-direction between the second heat sink 246 and the surfaces 201, 202 (e.g., lid, base) of the chassis 200. However, the example damper arrangements of FIGS. 3A-3F can additionally or alternatively be used in the x- or y-axis directions of the chassis 200.

FIG. 3A illustrates an example in which the damping material(s) 230 define damping layers along the fourth and fifth surfaces 236, 238 of the second heat sink 246. For example, the damping material(s) 230 can be chemically fastened to interior faces of the chassis surfaces 201, 202 of the chassis 200 or can be secured via a friction fit between the chassis surfaces 201, 202 and the corresponding surfaces 236, 238 of the second heat sink 246. FIG. 3B illustrates an example in which the damping material 230 between the base surface 202 and the fifth surface 238 of the second heat sink 246 is coupled to the base surface 202 via the retainers 232 (e.g., screws or other mechanical fasteners). In some examples, the damping material 230 between the lid 201 and the fourth surface 236 of the second heat sink 246 is additionally or alternatively coupled to the lid 201 via the retainer(s) 232.

FIGS. 3C and 3D illustrate example damper arrangements in which a gap 300 is defined between the damping material 230 and the lid 201 (as shown in FIG. 3C) or between the damping material 230 and the second heat sink 246 (as shown in FIG. 3D). In the example of FIG. 3C, the damping material 230 can be chemically fastened to the fourth surface 236 of the second heat sink 246. FIG. 3E shows an example in which the gap 300 is defined between the lid 201 and the fourth surface 236 of the second heat sink 246 and the damping material 230 is (e.g., only) between the base surface 202 of the chassis 200 and the fifth surface 238 of the second heat sink. The gap 300 can accommodate, for example, mounts that enable the chassis 200 to be coupled to a rack. Although the gap 300 is shown between the lid 201 and the fourth surface 236 of the second heat sink 246 in FIGS. 3C-3E, the gap 300 can additionally or alternatively be defined between the base surface 202 of the chassis 200 and the fifth surface 238 of the second heat sink 246.

The damping materials 230 shown in FIGS. 3A-3E can have different shapes and/or sizes than shown in the figures. For example, FIG. 3F illustrates an example in which a damping layer is defined by pieces of the damping material 230 disposed about the second heat sink 246. The piece-wise nature of the damping material 230 can enable varying amounts of the damping material 230 to be placed in the chassis 200 based on the amount of damping to be provided. The amount of damping material 230 in the chassis 200 can be selected based on factors such as a mass of the second heat sink 246, a distance between the first heat sink 244 (FIG. 2) and the second heat sink 246, weights of other components carried by the chassis 200, etc.

FIG. 4 is a schematic top view of the example chassis 200 of FIG. 2 and illustrates the damper 228 along the y-axis for mitigation of loads experienced by the second heat sink 246 in the y-direction. In the example of FIG. 4, the damping material 228 is between a first sidewall 400 of the chassis 200 and the third surface 235 of the second heat sink 246. In the example of FIG. 4, the damping material 228 is also disposed between a second sidewall 402 of the chassis 200 and fourth surface 404 of the second heat sink 246 that is opposite the third surface 235. Although in the example of FIG. 4, the damping material 228 is shown in a piece-wise arrangement as strips of damping material 228 extending along the respective sidewalls surfaces 400, 402, the damping material 228 can have other shapes and/or sizes. In some examples, the damping material 228 can be mechanically fastened to the sidewall(s) 400, 402 via the retainer(s) 232.

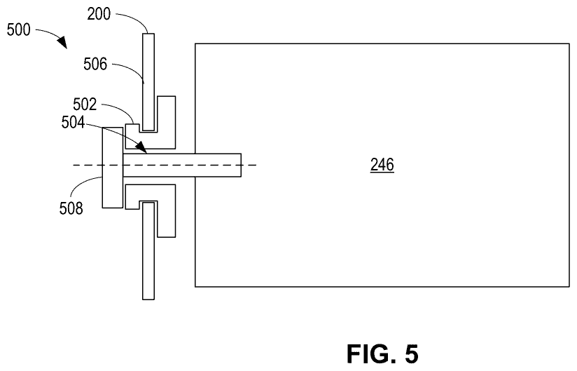

FIG. 5 illustrates an example damper 500 that may be used with the example chassis 200 of FIG. 2 to provide damping for the second heat sink 246. The example damper 500 of FIG. 5 includes a damping grummet 502. The damping grummet 502 can extend through an opening 504 defined in a sidewall 506 (e.g., which can include one of the sidewalls 400, 402 of FIG. 4). In the example of FIG. 5, the damping grummet 502 couples to portions of the sidewall 506 defining the opening 504 and/or is shaped around the portions of the sidewall 506 defining the opening 504. In some examples, the damping grummet 502 is coupled to or extends through other portions of the chassis 200, such as an interior wall of the chassis 200 that defines a pan (e.g., the pan 109 of FIG. 1) in which the second heat sink 246 sits. The damping grummet 502 can include rubber, silicone, etc. A shape and/or size of the damping grummet 502 can differ from the example shown in FIG. 5. The shape and/or size of the damping grummet 502 can be based on, for example, properties (e.g., size, shape, material) of the portion of the chassis 200 to which the damper 500 is to be coupled.

The example damper 500 of FIG. 5 includes a fastener 508. The fastener 508 can be a screw, a rivet, a pin, etc. As shown in FIG. 5, the fastener extends through the damping grummet 502 via the opening 504 of the sidewall 506 of the chassis 200 to couple with the second heat sink 246. Thus, the damper 500 of FIG. 5 couples one end of the second heat sink 246 to the chassis sidewall 506. In the example of FIG. 5, the damper 500 constrains the second heat sink 246 but does not rigidly fix the second heat sink 246; rather, the second heat sink 246 can still move or float within the chassis 200.

A main source of vibrational forces experienced by the second heat sink 246 typically originate from vibration of the chassis wall due to external forces (e.g., during transport). Thus, the example damper 500 of FIG. 5 mitigates the vibrations and shock forces experienced by the second heat sink 246 from chassis wall vibrations. Therefore, the example damper 500 of FIG. 5 can reduce the effects of vibrations or shocks on the LGA stack or assembly (e.g., the first heat sink 244, the LGA package 206, the LGA socket 242, the pins 208 of FIG. 2) to which the second heat sink 246 is thermally coupled. However, the coupling between the damper 500 and the second heat sink 246 still permits the second heat sink 246 to float or move, thereby providing for tolerance with respect to the LGA package 206 and the LGA socket 242. Although FIG. 5 illustrates one damper 500, in some examples, additional dampers 500 can be used to couple the second heat sink 246 to the chassis 200 (while maintaining the ability of the second heat sink 246 to move or float relative to the chassis 200). Also, in some examples, the damping grummet or other damping material 502 can be coupled to the second heat sink 246 instead of, or in addition to, the coupling of the damping material 502 to the sidewall 506.

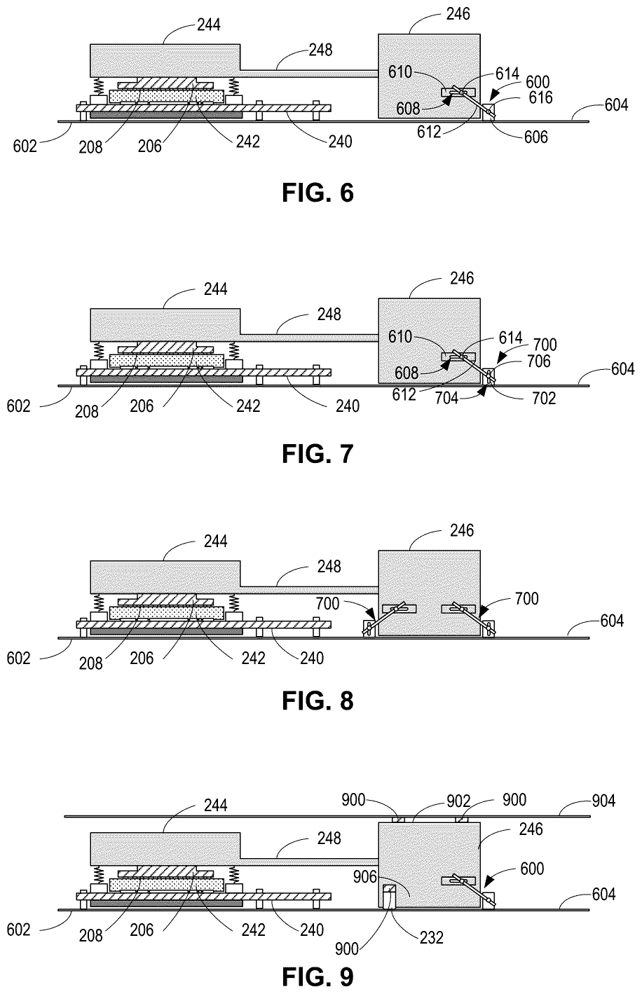

FIG. 6 illustrates a first example support assembly 600 that may be used to carry the second heat sink 246 of FIG. 2 in a chassis 602 (which may correspond to the chassis 200 of FIG. 2). For illustrative purposes, a portion of the chassis 602 including a base surface 604 is shown in FIG. 6. As disclosed in connection with FIG. 2, the second heat sink 246 floats or is moveable (e.g., laterally moveable) within the area (e.g., the area 109 of FIG. 1) of the chassis 602 in which the second heat sink 246 sits. The example support assembly 600 of FIG. 6 can be used to define the allowable range of movement by the second heat sink 246 to reduce lateral movement of the first heat sink 244 to which the second heat sink 246 is coupled. Reducing lateral movement of the first heat sink 244 mitigates risks such as misalignment, scratching, cracking, etc. with respect to the LGA package 206, the LGA socket 242, and the pins 208.

The example support assembly 600 of FIG. 6 includes a hinge 606. The hinge 606 is coupled to the base surface 604 of the chassis 602 (e.g., via one or more mechanical fasteners). In the example of FIG. 6, a slot or, more generally, an aperture 608 is defined in a surface 610 (e.g., a metal surface) of the second heat sink 246. In other examples, the slot 608 is defined in a surface that is coupled to the surface 610 of the second heat sink 246. A connecting rod 612 includes a first end having a roller 614 (e.g., a pin, a ball) that is moveably (e.g., slidably) received in the slot 608. A second end of the connecting rod 612 is coupled to the hinge 606 via a pin 616 or other fastener.

In the example of FIG. 6, the range of movement of the second heat sink 246 can be defined by the distance in which the roller 614 is permitted to slide within the slot 608. Sliding of the roller 614 is controlled by the hinge 606 via movement of the connecting rod 612 about the pin 616. For example, tightening the coupling between the hinge 606 and the pin 616 of the connecting rod 612 can limit the amount by which the connecting rod 612 can pivot, thereby limiting the amount by which the roller 612 can slide within the slot 608 and, thus, limiting lateral movement of the second heat sink 246. Conversely, allowing the connecting rod 612 to pivot more freely about the pin 616 provides for increased lateral movement of the second heat sink 246 via sliding of the roller 614 within the slot 608. The amount by which the roller 614 is permitted to slide within the slot 608 can be selected based on, for example, the mass of the second heat sink 246, an expected amount of vibrations or shock loads, etc. Thus, the example support assembly 600 of FIG. 6 provides for controlled floating of the second heat sink 246 by defining a range of movement of the second heat sink 246 relative to the chassis 602.

In some examples, the slot 608 and the roller 614 are a rack and pinion. In some examples, the roller 614 (e.g., a screw pin) can be tightened within the slot 608 to restrict the range of movement of the second heat sink 246 in addition to or as an alternative to tightening the pin 616 at the hinge 606. In some examples, tightening the roller 614 in the slot 608 and the pin 616 at the hinge 606 prevents or substantially prevents movement of the second heat sink 246. Also, although in the example of FIG. 5, the slot 608 is defined with respect to the second heat sink 246, in other examples, the hinge 606 can be coupled to the second heat sink 246 and a surface including the slot 608 can be coupled to the base surface 604 of the chassis 602.

FIG. 7 illustrates a second example support assembly 700 that may be used to carry the second heat sink 246 of FIG. 2 in the chassis 602. Similar to the first example support assembly 600 of FIG. 6, the example support assembly 700 includes the slot 608 defined in the surface 610 of the second heat sink 246 or coupled to the second heat sink 246. The example support assembly 700 includes the connecting rod 612 including the roller 614 moveably (e.g., slidingly) received in the slot 608. In the example of FIG. 7, a hinge 702 is coupled the base surface 604 of the chassis 602 and includes a second slot or aperture 704 defined therein. In the example of FIG. 7, the second end of the connecting rod 612 includes a second roller 706 (e.g., a pin, a ball) that is moveably received in the second slot 704. Thus, in the example of FIG. 7, the range of movement of the second heat sink 246 is defined by the movement of the first roller 614 within the first slot 608 at the second heat sink 246 and movement of the second roller 706 within the second slot 704 at the hinge 702.

FIG. 8 illustrates an example in which two of the second support assemblies 700 of FIG. 7 are used to define the range of movement of the floating second heat sink 246 in the chassis 602. The use of the two support assemblies 700 can be selected based on, for example, a mass of the second heat sink 246, expected vibration or shock loads, a size of the area (e.g., the pan 109) in which the second heat sink 246 is located in the chassis 602, placement of other components in the chassis 602, etc.

FIG. 9 illustrates an example in which the first support assembly 600 is used with a damper 900 to control movement of the second heat sink 246 in the chassis 602 and further mitigate the effects of vibrations and shocks through damping. Although the example of FIG. 9 includes the first support assembly 600, the second support assembly 700 of FIG. 7 could be used.

In the example of FIG. 9, the damper 900 (e.g., the dampers 222, 228, 230 of FIG. 2) is disposed proximate to the second heat sink 246 along one or more axes. For example, damper 900 is disposed between a first surface 902 of the second heat sink 246 and a lid 904 of the chassis 602. Also, the damper 900 can extend along at least a portion of a second surface 906 of the second heat sink 246 and a sidewall (not shown) of the chassis 602. The damper 900 can be supported by retainer(s) 232 as disclosed in connection with FIG. 2.

Although the examples of FIGS. 2-9 are disclosed in connection with providing damping with respect to the second or remote heat sink 246 of FIG. 2, in some examples, damping may additionally or alternatively be provided with respect to the first heat sink 244 of FIG. 2 (i.e., the heat sink most proximate to or disposed over the semiconductor chip package 206 of FIG. 2).

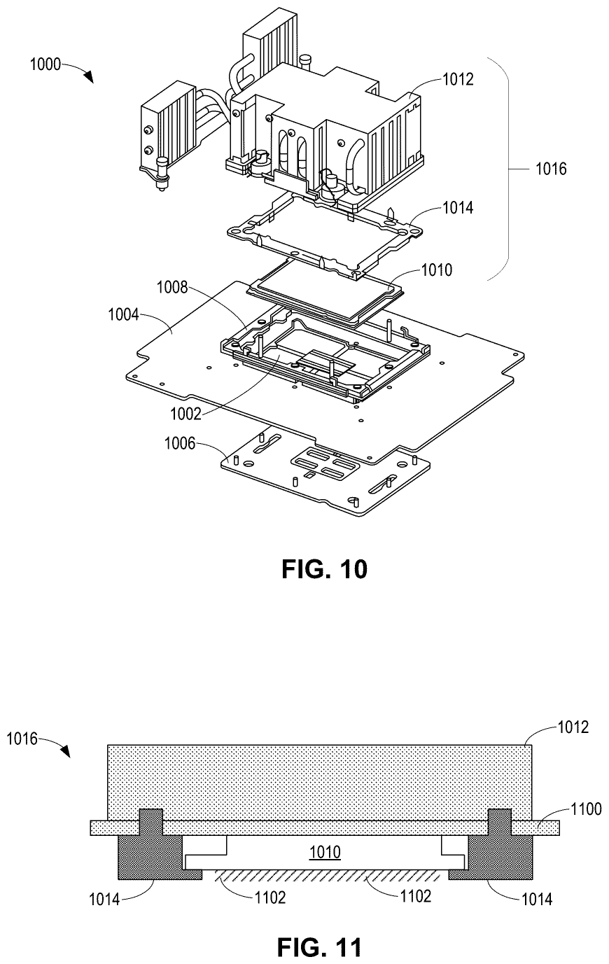

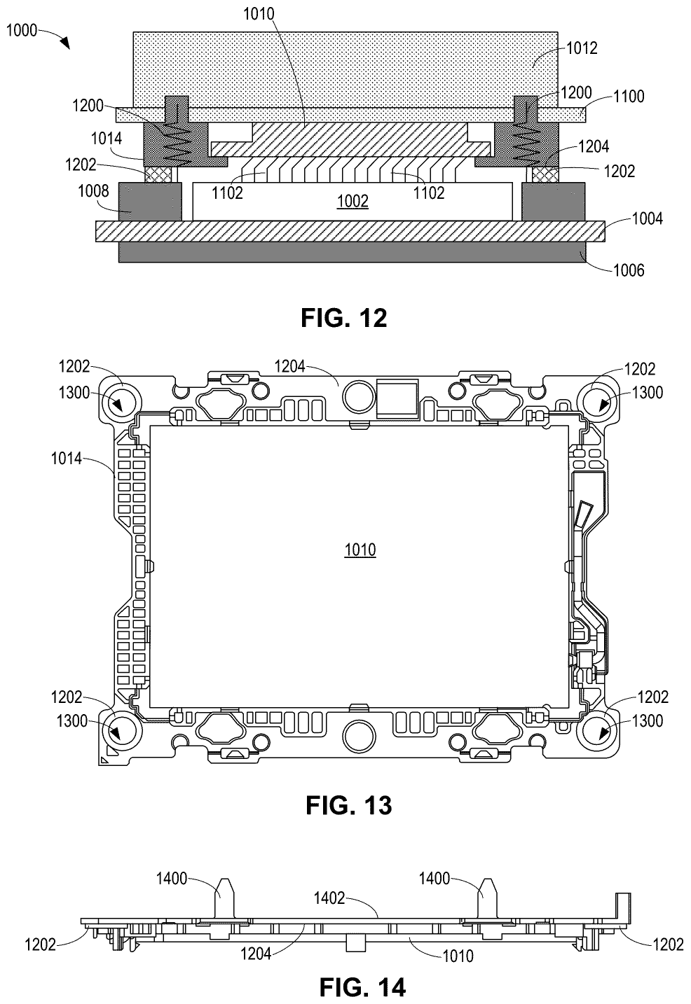

FIG. 10 is an exploded view of an example land grid array (LGA) assembly 1000 including an LGA socket 1002 (e.g., the LGA socket 242 of FIG. 2), a semiconductor chip or LGA package 1010 (e.g., the LGA package 206 of FIG. 2), pins (FIG. 11, e.g., pins 208 of FIG. 2), and a heat sink 1012 (e.g., the first heat sink 244 of FIG. 2). The LGA assembly 1000 can be carried by, for example, the chassis 200 of FIG. 2. As shown in FIG. 10, the LGA socket 1002 is coupled to a printed circuit board (PCB) 1004. A back plate 1006 is on a first side of the PCB 1004 and couples with a bolster plate 1008 on a second side of the PCB 1004 via, for example, fasteners extending through the PCB 1004. The bolster plate 1008 surrounds the LGA socket 1002. The semiconductor chip package 1010 is electrically coupled to the LGA socket 1002. The heat sink 1012 sits over the LGA package 1010 in the orientation shown in FIG. 10. Loading mechanism(s) (FIG. 12), such as springs, can be used to regulate loads placed on the LGA package 1010 and the LGA socket 1002 by the heat sink 1012. Although a remote or second heat sink (e.g., the second heat sink 246 of FIG. 2) is not shown in FIG. 10, in some examples, the heat sink 1012 of FIG. 10 is thermally coupled to a second heat sink (e.g., via the heat pipes 248 of FIG. 2).

In the example of FIG. 10, the LGA assembly 1000 includes a carrier 1014 to facilitate placement of the LGA package 1010 relative to the heat sink 1012. The carrier 1014 is disposed between the bolster plate 1008 and the heat sink 1012. The heat sink 1012, the LGA package 1010, and the carrier 1014 can define a heat sink assembly 1016.

FIG. 11 is a schematic illustration of the heat sink assembly 1016 of FIG. 10 including the heat sink 1012, the LGA package 1010, and the carrier 1014. As illustrated in FIG. 11, a portion of the LGA package 1010 is supported by the carrier 1014. The carrier 1014 is coupled to a base 1100 of the heat sink 1012 (e.g., via fasteners). The LGA package 1010 is electrically coupled to the LGA socket 1002 via pins 1102 of the LGA socket 1002 (FIG. 10).

The heat sink 1012 of FIG. 10 can be subject to vibrational or shock forces that can cause the heat sink 1012 to move laterally or to rock (e.g., during transport of the chassis in which the LGA assembly 1000 is disposed). As a result, the LGA package 1010 may move or shift relative to the LGA socket 1002. The movement of the LGA package 1010 can result in fretting or scratching of the metal pad of the semiconductor chip package 1010 due to, for example, friction between the pins 1102 and the LGA package 1010. To prevent or substantially reduce the risk of fretting or scratching at the LGA package 1010, dampers (e.g., shock absorbers) can be provided proximate to the carrier 1014 at locations where the risks of fretting in connection with the pins 1102 of the LGA socket 1002 is increased (e.g., proximate to edges or corners of the LGA package 1010).

FIG. 12 is a schematic view of the example LGA stack or assembly 1000 of FIG. 10 including springs 1200 to regulate loads placed on the LGA package 1010 and the LGA socket 1002 by the heat sink 1012. As illustrated in FIG. 12, the springs 1200 can be disposed between the base 1100 of the heat sink 1012 and the bolster plate 1008.

In the example of FIG. 12, a damper 1202 is disposed between the carrier 1014 and the bolster plate 1008. In particular, the damping material 1202 is coupled to (e.g., embedded in, attached to, secured to) a first side 1204 of the carrier 1014 that faces the bolster plate 1008. Coupling the damping material 1202 to the carrier 1014 reduces movement of the damping material 1202 over time. Also, in some examples, coupling (e.g., embedding) the damping material 1202 to the carrier 1014 can address space limitations between the heat sink base 1100 and the bolster plate 1008. The damping materials 1202 can include, for example, rubber (e.g., polyurethane foam), silicone, etc.

FIG. 13 illustrates example locations of the damping material 1202 on the first side 1204 of the carrier 1014 of FIG. 10. As shown in FIG. 13, the damping material 1202 is coupled to the first side 1204 of the carrier 1014 about openings 1300 defined in the carrier 1014 and, in particular, the openings 1300 located proximate to corners or ends of the carrier 1014. The openings 1300 can receive fasteners that couple, for example, the bolster plate 1008, the carrier 1014, and the heat sink 1012. The placement of the damping material 1202 about the openings 1300 located at the corners of the carrier 1014 can be selected because transfer of vibrational forces from the heat sink 1012 to the LGA package 1010 that could cause shifting of the LGA package 1010 relative to the LGA socket 1002 may be more likely to occur at such locations. However, the damping materials 1202 can be located about other openings 1300 in defined in the carrier 1014, coupled to the first side 1204 of the carrier 1014 at locations different than the openings 1300, etc. The carrier 1014 can made of a plastic material and the damping material 1202 can be, for example, over-molded into the surface 1204 of the carrier 1014.

FIG. 14 is a side view of the example carrier 1014 of FIG. 10, showing the coupling of the damping material 1202 to the first side 1204 of the carrier 1014. As shown in FIG. 14, the damping material 1202 extends from the first side 1204 of the carrier 1014 such that the damping material 1202 is between the carrier 1014 and the bolster plate 1008 (FIG. 12) when the carrier 1014 is in the LGA assembly 1000 of FIG. 10. As also shown in FIG. 14, the carrier 1014 includes tabs 1400 that extend from a second, opposing surface 1402 of the carrier 1014. The tabs 1400 can help to couple the heat sink 1012 to the carrier 1014, limit movement of the heat sink 1012, etc.

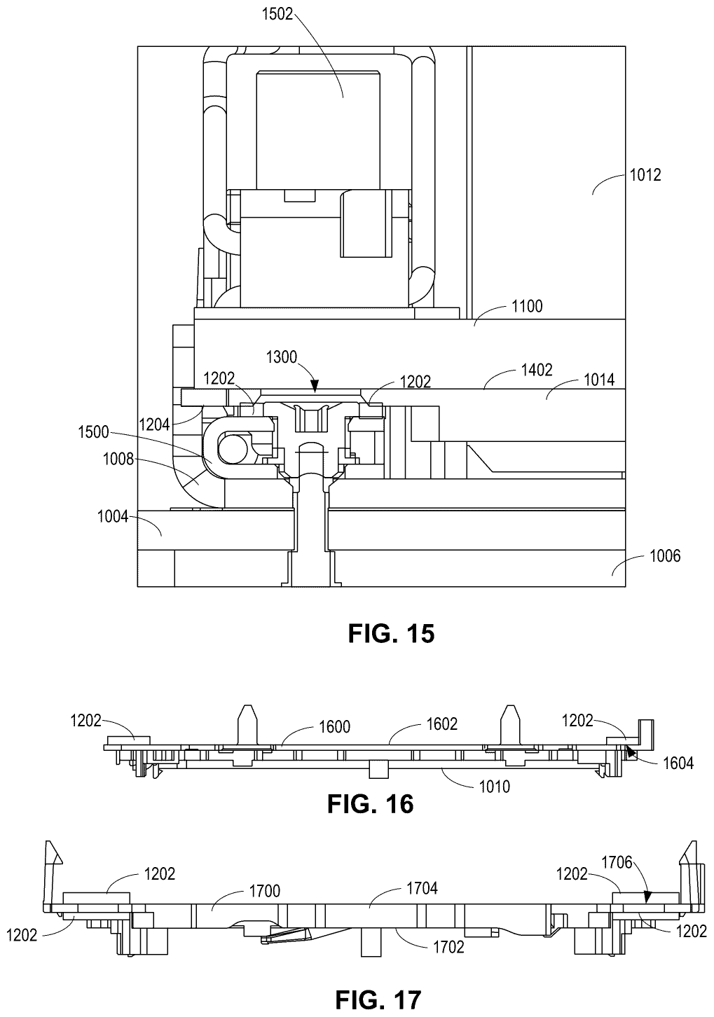

FIG. 15 is a partial cross-sectional view of a portion of the example LGA assembly 1000 of FIG. 10 including the damping material 1202 disposed about one of the openings 1300 of the carrier 1014. As shown in FIG. 15, the damping material 1202 is between the first side 1204 of the carrier 1014 and the bolster plate 1008. In particular, the damping material 1202 is disposed between the first side 1204 of the carrier 1014 and supports 1500 of the bolster plate 1008 that engage the carrier 1014. The base 1100 of the heat sink 1012 is supported by the second surface 1402 of the carrier 1014. A fastener 1502 (e.g., a screw) extends through the heat sink base 1100 and can be used to, for example, actuate or control the loading springs 1200 (e.g., control an amount of deflection of the loading springs 1200 of FIG. 12).

FIG. 16 illustrates another example carrier 1600 to support the LGA package 1010 of FIG. 10. The example carrier 1600 of FIG. 16 includes the damping material 1202 disposed on a surface 1602 of the carrier 1600, or a surface that faces away from the bolster plate 1008 in the example of FIG. 10. In such examples, the damping material 1202 is between the carrier 1600 and the base 1100 of the heat sink 1012 in the heat sink assembly 1016 of FIG. 10. In the example of FIG. 16, the damping material 1202 is disposed about openings 1604 (e.g., the openings 1300) defined in the carrier 1600. The damping material 1202 can additionally or alternatively be located elsewhere along the surface 1602 than shown in FIG. 16.

FIG. 17 illustrates another example carrier 1700 including the damping material 1202 located on (e.g., coupled to, embedded in) a first surface 1702 and an opposing second surface 1704 of the carrier 1700. In the example of FIG. 17, the damping material 1202 is disposed about openings 1604 (e.g., the openings 1300) defined in the carrier 1600. Thus, the example of FIG. 17 provides for damping between the carrier 1700 and the base 1100 of the heat sink 1012 and between the carrier 1700 and the bolster plate 1008 of FIG. 10. In the example of FIG. 17, the damping material 1202 is disposed about openings 1706 (e.g., the openings 1300) defined in the carrier 1700. The damping materials 1202 can additionally or alternatively be located elsewhere along the surfaces 1702, 1704 than shown in FIG. 17.

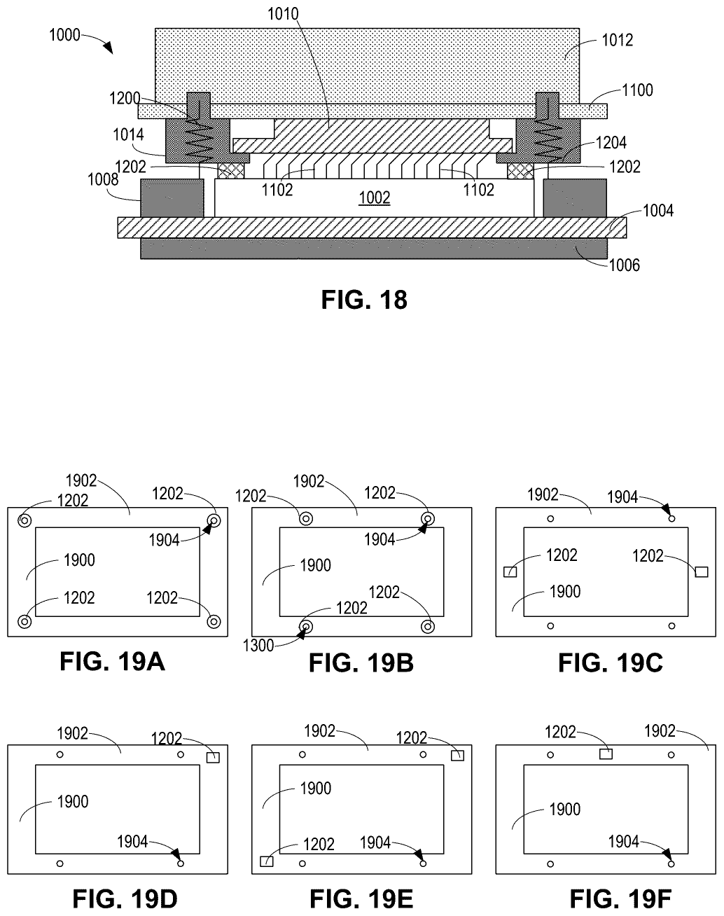

FIG. 18 is a schematic illustration of the example LGA assembly 1000 of FIG. 10 in which the damping material 1202 is coupled to the first surface 1204 of the carrier 1014 at locations other than about the openings (e.g., the openings 1300, 1604, 1706) defined in the carrier 1014. For example, in FIG. 18, the damping material 1202 is disposed between the carrier 1014 and the LGA socket 1002 to mitigate effects of vibrational forces from the heat sink 1012 on the LGA socket 1002, the pins 1102, and the LGA package 1010. In some examples, the damping material(s) 1202 can additionally extend from the carrier 1014 (e.g., about the openings 1300, 1604, 1706 of the carrier 1014) to the bolster plate 1008 as disclosed in connection with FIGS. 12-17.

FIG. 19A-19F illustrate example locations of the damping material 1202 on a first side 1900 (e.g., the first side 1204 of the carrier 1014) of a carrier 1902 (e.g., the carrier 1014, 1600, 1700 of FIGS. 10, 16, 17). Although the examples of FIGS. 19A-19F are shown on the first side 1900 of the carrier 1014, the examples of FIGS. 19A-19F can additionally or alternatively be included on an opposing second side of the carrier 1900 (e.g., the second side 1402 of the carrier 1014). As shown in FIGS. 19A-19F, the damping materials 1202 can be disposed about openings 1904 defined in the carrier 1900, at portion(s) of the carrier 1900 not including the openings 1904, etc. In some examples, the damping material(s) 1202 are disposed in cutout(s) or groove(s) defined in the surface(s) of the carrier 1014. The damping material(s) 1202 can also have different shapes and/or sizes than shown in FIGS. 19A-19F. Also, the damping material(s) 1202 can be coupled to the carrier 1014 at locations other than those shown in FIGS. 19A-19F. Also, the carrier 1014 can include additional or fewer openings 1904 than shown in FIGS. 19A-19F, openings at different locations than shown in FIGS. 19A-19F, different combinations of openings (e.g., the openings 1904 of FIG. 19A and the openings 1904 of FIG. 19B), etc.

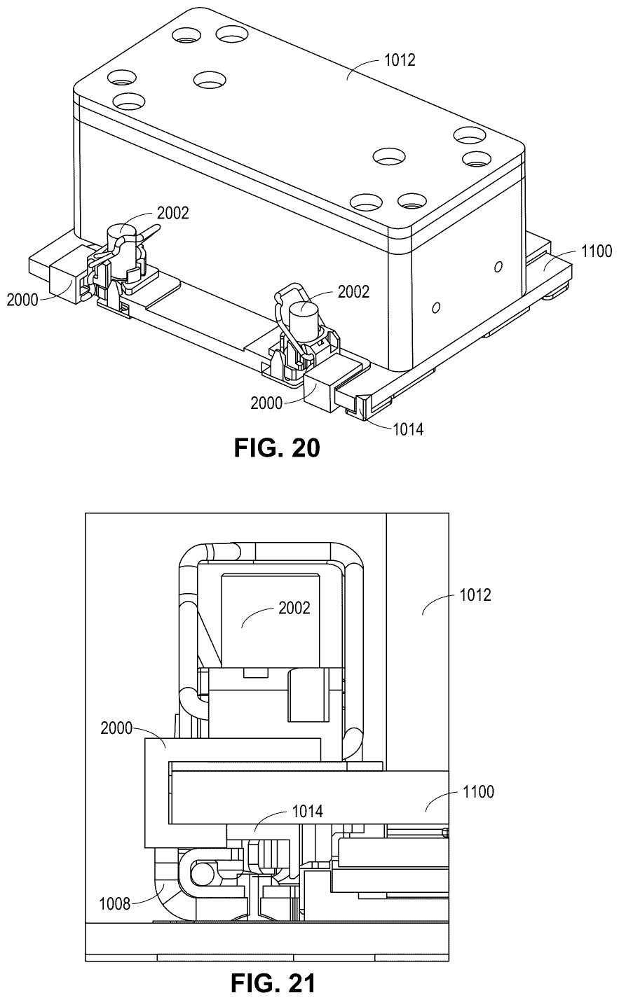

Although the examples of FIGS. 12-19F are discussed in connection with the damping material 1202 being carried by the carrier 1014, 1600, 1700, 1900 that supports the semiconductor chip package 1010, in some examples, the damper is coupled to the heat sink 1012. In such examples, the damper is not supported or not substantially supported by the carrier 1014. FIG. 20 illustrates the example heat sink 1012 and the carrier 1014 of FIG. 10. In the example of FIG. 20, a damper 2000 is coupled to the base 1100 of the heat sink 1012. The damping material 2000 can have a shape (e.g., a C-shape) such that the damping material 2000 wraps around an edge of the heat sink base 1100, as shown in FIG. 20. The damping material 2000 can be proximate to, for example, fastener(s) 2002 that control actuation of the loading springs 1200 (FIG. 12). Thus, in the example of FIG. 20, the damping material 2000 is disposed proximate to locations where the heat sink 1012 couples with other components of the LGA assembly 1000 such as the carrier 1014 to mitigate the effects of vibration and shock forces experienced by the heat sink 1012 on, for example, the LGA package 1010. However, the damping material 2000 can be disposed at other locations along the base 1100. Also, the example of FIG. 20 can include additional or less damping material 2000, damping material 2000 having different shapes, sizes, etc.

FIG. 21 is a partial cross-sectional view of a portion of the example LGA assembly 1000 of FIG. 10 including the damping material 2000 coupled to the base 1100 of the heat sink 1012, as disclosed in connection with FIG. 20. As shown in FIG. 21, the damping material 2000 wraps around the base 1100 of the heat sink 1012. A portion of the damping material 2000 can be disposed between the heat sink base 1100 and the bolster plate 1008. As shown in FIG. 21, the damping material 2000 can extend proximate to the carrier 1014 to secure the damping material 2000 to the heat sink base 1100. In some examples, the damping material 2000 is used with the examples of FIGS. 12-19F in which the damping material 1202 is coupled to the carrier 1014.

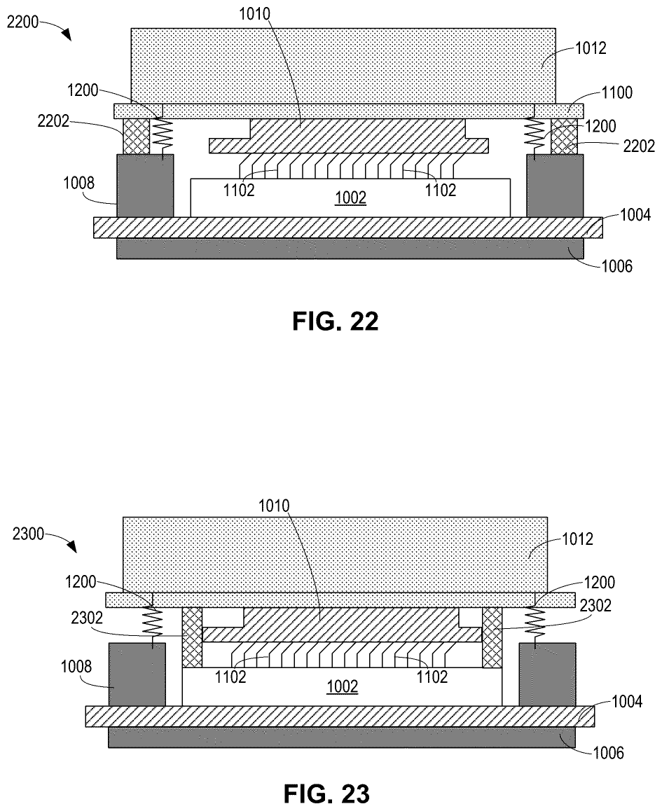

In some examples, a carrier (e.g., the carrier 1014, 1600, 1700, 1900) is not used in connection with an LGA assembly (e.g., the LGA assembly 1000 of FIG. 10). However, damping can still be provided with respect to the heat sink 1012. FIG. 22 is a schematic illustration of an example LGA assembly 2200 that corresponds to the example LGA assembly 1000 of FIG. 10, but does not include the carrier 1014, 1600, 1700, 1900. As illustrated in FIG. 22, a damper 2202 is disposed between (e.g., directly between) the base 1100 of the heat sink 1012 and the bolster plate 1008. In some examples, the damping material 1202 can be coupled to (e.g., attached to, embedded in a surface of, extend from) the heat sink base 1100.

FIG. 23 is a schematic illustration of another example LGA assembly 2300 that corresponds to the example LGA assembly 1000 of FIG. 10, but does not include the carrier 1014, 1600, 1700, 1900. As illustrated in FIG. 23, a damper 2302 is disposed between the base 1100 of the heat sink 1012 and the LGA socket 1002. In some examples, the damping material 1202 can be coupled to (e.g., attached to, embedded in a surface of, extend from) the heat sink base 1100. In some examples, the LGA assembly 2300 can additionally include the damping material 2202 disposed between the heat sink base 1100 and the bolster plate 1008 as disclosed in connection with FIG. 22.

Thus, in the examples of FIGS. 12-23, the dampers 1202, 2000, 2202, 2302 can be placed in various locations relative to the LGA assembly 1000, 2200, 2300 (e.g., the heat sink 1012, the LGA package 1010, the LGA socket 1002, the socket pins 1102) based on factors such as mass of the heat sink 1012, available space between the heat sink base 1100 and the bolster plate 1008, whether or not the carrier 1014 is used, etc. The examples of FIGS. 12-23 allow for flexible placement of the damping materials 1202, 2000, 2202, 2302 relative to the LGA assembly 1000, 2200, 2300. For example, the damping materials 1202, 2000, 2202, 2302 may be placed at edges, corners, fastener locations, etc. where the risk of LGA pin-pad vibration fretting may be greater than other portions of the LGA assembly 1000, 2200, 2300. Further, coupling the damping materials 1202, 2000, 2202, 2302 to hardware such as the carrier 1014 or the heat sink base 1100 reduces movement (e.g., shifting) of the damping materials 1202, 2000, 2202, 2302 over time.

Although the examples of FIGS. 2-9 regarding damping for the remote heat sink 246 and the examples of FIGS. 10-23 regarding damping for the first heat sink 244 are discussed separately, one or more of the examples of FIGS. 2-9 could be combined with one or more of the examples of FIGS. 10-23 to provide for damping at the first heat sink 244 and the second heat sink 246. Put another way, in a single chassis 200, damping at the first heat sink 244 can be provided via one more of the one or more of the examples of FIGS. 2-9 and damping for the second heat sink 246 can be provided via the examples of FIGS. 10-23.

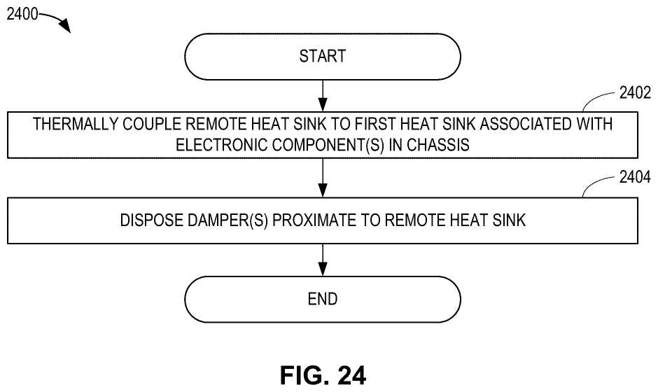

FIG. 24 is a flowchart of a first example method 2400 for providing damping at the remote heat sink 246 of FIG. 2. The example method 2400 of FIG. 24 includes thermally coupling the second or remote heat sink 246 to the first heat sink 244 associated with electronic components such as the LGA package 206 in the chassis 200 of FIG. 2 via, for example, the heat pipe(s) 248 (block 2402). The example method 2400 of FIG. 24 includes disposing damper(s) 222, 228, 230 proximate to the second or remote heat sink 246 (block 2402). For example, the damper(s) 222, 228, 230 can be coupled to the chassis 200 (e.g., via the retainer(s) 232) in one or more of the x, y, and/or z directions, as disclosed in connection with FIGS. 2-4.

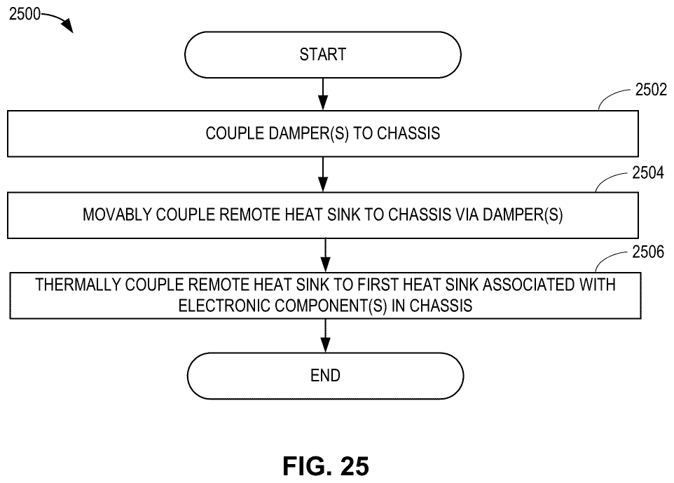

FIG. 25 is a flowchart of a second example method 2500 for providing damping at the remote heat sink 246 of FIG. 2. The example method 2500 of FIG. 25 begins with coupling the damper 500 of FIG. 5 (e.g., the damping grummet 502) to the chassis 200 of FIG. 2 (e.g., a wall of the chassis 200) (block 2502). The example method 2500 includes movably coupling the remote heat sink 246 to the chassis 200 of FIG. 2 via the fastener 508 of the damper 500 of FIG. 5 (block 2504). For example, the remote heat sink 246 can be coupled to a wall of the chassis 200 via the fastener 508 that couples the chassis 200, the damping grummet 502, and the remote heat sink 246. The example method 2500 includes thermally coupling the second heat sink 246 to the first heat sink 244 associated with electronic components such as the LGA package 206 and the LGA socket 242 in the chassis 200 via, for example, the heat pipe(s) 248 (block 2506).

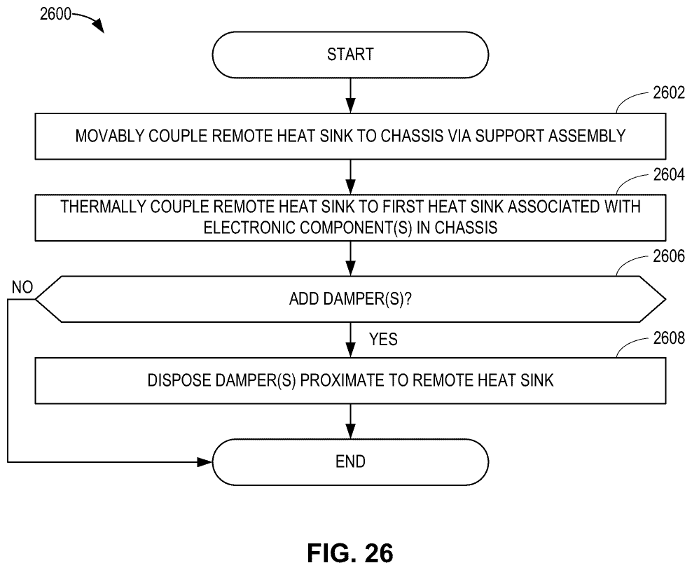

FIG. 26 is a flowchart of a third example method 2600 for providing damping at the remote heat sink 246 of FIG. 2. The example method 2600 of FIG. 26 includes movably coupling the remote heat sink 246 to the chassis 200 of FIG. 2 via one of the support assemblies 600, 700 of FIGS. 6-9 (block 2602). As disclosed in connection with FIGS. 6-9, the support assemblies 600, 700 pivotably couple the remote heat sink 246 to the chassis 200 (e.g., via hinges 606, 702, the sliding roller(s) 614, 706 and the connecting rod 612) to define a range of movement of the floating remote heat sink 246 in the chassis 200, thereby limiting movement of the remote heat sink 246 that can cause rocking or movement of the first heat sink 244. The example method 2600 includes thermally coupling the remote heat sink 246 to the first heat sink 244 associated with electronic components such as the LGA package 206 and the LGA socket 242 in the chassis 200 via, for example, the heat pipe(s) 248 (block 2604). In some examples, damper(s) 900 can be added to the chassis 200 proximate to the remote heat sink 246 as disclosed in connection with FIG. 9 (blocks 2606, 2608).

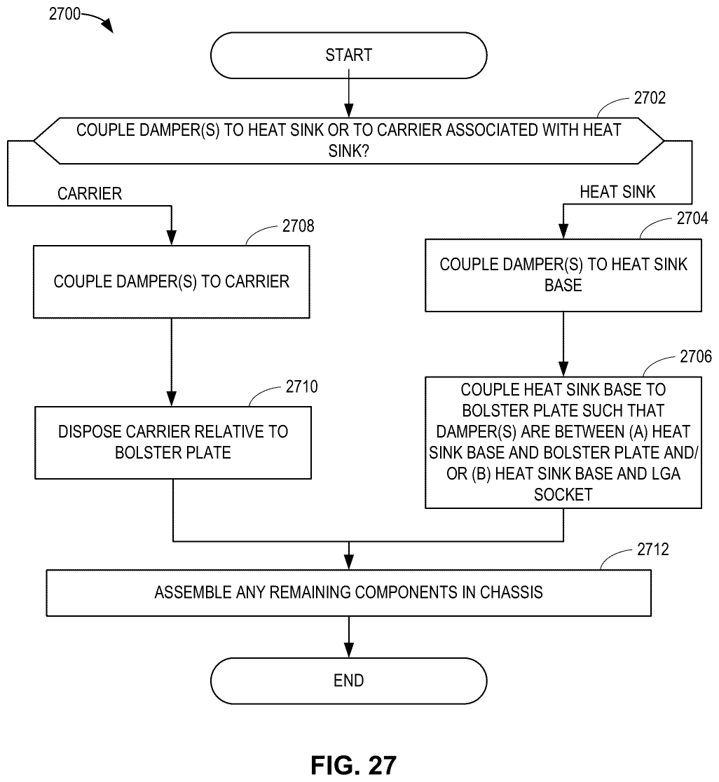

FIG. 27 is a flowchart of an example method 2700 for providing damping at the first heat sink 244, 1012 of FIGS. 2 and 10. The example method 2700 begins with determining if the damper(s) 2000, 2202, 2302 should be coupled to the heat sink 244, 1012 (e.g., the base 1100 of the heat sink 1012 of FIG. 11) or to the carrier 1014, 1600, 1700, 1900 in examples in which the carrier 1014, 1600, 1700, 1900 is used to support the semiconductor chip package 206, 1010 (block 2702). In examples in which the damper(s) 2000, 2202, 2302 are to be coupled to the heat sink 244, 1012, the example method 2700 includes coupling (e.g., attaching, embedding, wrapping around) the damper(s) 2000, 2202, 2302 relative to the heat sink base 1100 (e.g., via cutouts in the base 1100, wrapping the damping material around edges of the base 1100) as disclosed in connection with FIGS. 20, 21, 22, and/or 23 (block 2704). The example method 2700 includes coupling the heat sink base 1100 to the bolster plate 1008 of FIG. 10 to cause the damper(s) 2202, 2302 to be located between (e.g., directly between), for example, the heat sink base 1100 and the bolster plate 1008 and/or between the heat sink base 1100 and the LGA socket 242, 1002 (block 2706).

In examples in which the damper 1202 is to be coupled to the carrier 1014, 1600, 1700, 1900 the example method 2700 includes coupling the damper 1202 to the carrier 1014, 1600, 1700, 1900 via, for example, cutouts in the surface(s) 1204, 1402 of the carrier 1014, about openings 1300, 1904 defined in the carrier 1014, 1600, 1700, 1900, etc. (block 2708). The example method 2700 of FIG. 27 includes disposing the carrier 1014, 1600, 1700, 1900 relative to the bolster plate 1008 (block 2710).

The example method 2700 ends with assembling any remaining components in the chassis 200 of FIG. 2, such as the LGA package 206, 1010 and heat sink 244, 1012 relative to the carrier 1014, thermally coupling a second or remote heat sink 246, etc. (block 2712).

While example manners of providing damping for the first and second heat sinks 244, 246 of FIGS. 2-23 are illustrated in FIGS. 24-27, one or more of the elements, processes and/or devices illustrated in FIGS. 24, 25, 26, and/or 27 may be combined, divided, re-arranged, omitted, eliminated and/or implemented in any other way. Also, one or more of the methods 2400, 2500, 2600, 2700 disclosed in connection with FIGS. 24, 25, 26, and/or 27 may be combined with one or more of another method 2400, 2500, 2600, 2700 disclosed in connection with FIGS. 24, 25, 26, and/or 27. For example, one or more of the methods 2400, 2500, 2600 of FIGS. 24, 25 and 26 can be combined with the method 2700 of FIG. 27 to provide for damping at the first heat sink 244 and at the second heat sink 246.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that provide damping with respect to heat sink(s) that regulate temperature of electronic component(s). Examples disclosed herein mitigate the effects of vibrations when two heat sinks are coupled laterally in, for example, a 1U chassis. As a result, examples disclosed herein substantially reduce or prevent shifting of a semiconductor chip relative to a socket that could otherwise cause scratching, cracking, etc. of the socket. Examples disclosed herein provide for flexible placement of dampers, thereby providing for multi-directional damping with respect to one or more heat sinks in the chassis. Thus, examples disclosed herein improve operation of a machine.

Example damping assemblies for heat sinks and related methods are disclosed herein. Further examples and combinations thereof include the following:
Example 1 includes an apparatus comprising a chassis; a first heat sink associated with an electronic component in the chassis; a second heat sink coupled to the first heat sink, the second heat sink spaced apart from the first heat sink in the chassis; and damping material proximate to the second heat sink.
Example 2 includes the apparatus of claim 1, wherein the damping material includes a first damping material extending along at least a portion of a first surface of the second heat sink.
Example 3 includes the apparatus of claim 1 or 2, further including second damping material extending along at least a portion of a second surface of the second heat sink.
Example 4 includes the apparatus of any of claims 1-3, wherein the damping material coupled to a wall of the chassis.
Example 5 includes the apparatus of any of claims 1-4, wherein the second heat sink is coupled to the damping material.
Example 6 includes the apparatus of any of claims 1-5, wherein the second heat sink is moveable relative to the chassis.
Example 7 includes the apparatus of any of claims 1-6, wherein the damping material includes rubber or silicone.
Example 8 includes an apparatus comprising a chassis; a printed circuit board in the chassis; an electronic component electrically coupled to the printed circuit board; a first heat sink thermally coupled to the electronic component; a second heat sink coupled to the first heat sink, the second heat sink spaced apart from the first heat sink, the second heat sink moveable relative to the chassis; and a damper proximate to at least one of the first heat sink or the second heat sink in the chassis.
Example 9 includes the apparatus of claim 8, wherein the damper extends along at least a portion of a first surface of the second heat sink.
Example 10 includes the apparatus of any of claim 8 or 9, wherein the damper is one of (a) coupled to a wall of the chassis, a gap between the damper and the first surface of the second heat sink or (b) coupled to the first surface of the second heat sink, the gap between the damper and the wall of the chassis.
Example 11 includes the apparatus of any of claims 8-10, wherein the damper is supported by a fastener, the fastener coupled to a wall of the chassis, the wall of the chassis proximate to the first surface of the second heat sink.
Example 12 includes the apparatus of any of claims 8-11, wherein the damper is a first damper, the first damper extending in a first direction, and further including a second damper, the second damper extending along a second surface of the second heat sink in a second direction different than the first direction.
Example 13 includes the apparatus of any of claims 8-12, wherein the electronic component is supported by a carrier, the damper coupled to the carrier.
Example 14 includes the apparatus of any of claims 8-14, wherein the damper is carried by the first heat sink.
Example 15 includes an apparatus comprising a heat sink; a semiconductor chip package; a carrier between the heat sink and the semiconductor chip package, the carrier coupled to the heat sink; and damping material coupled to the carrier.
Example 16 includes the apparatus of claim 15, further including a bolster plate, wherein the damping material between the carrier and the bolster plate.
Example 17 includes the apparatus of claim 15 or 16, further including a socket, the socket to receive the semiconductor chip package, the damping material between the carrier and the socket.
Example 18 includes the apparatus of any of claims 15-17, wherein the damping material is disposed about an opening defined in the carrier.
Example 19 includes the apparatus of any of claim 15-18, wherein the damping material is disposed in a groove defined in a surface of the carrier.
Example 20 includes the apparatus of any of claims 15-19, wherein the wherein the damping material is coupled to a first surface of the carrier and further including second damping material coupled to a second surface of the carrier, the second surface opposite the first surface.
Example 21 includes the apparatus of any of claims 15-20, wherein the damping material is coupled to a first surface of the carrier, a second surface of the carrier coupled to the heat sink, the second surface opposite the first surface.
Example 22 includes an apparatus comprising a chassis; a first heat sink associate with an electronic component in the chassis; a second heat sink coupled to the first heat sink, the second heat sink spaced apart from the first heat sink in the chassis; and a hinge coupled to a wall of the chassis, the second heat sink pivotably coupled to the hinge.
Example 23 includes the apparatus of claim 22, further including a damper proximate to the second heat sink.
Example 24 includes the apparatus of any of claim 22 or 23, wherein the second heat sink is pivotably coupled to the hinge via a rod.
Example 25 includes the apparatus of any of claims 22-24, further including a slot in one of a surface of the second heat sink or a surface coupled to the second heat sink, a first end of the rod including a first roller, the first roller slidingly received within the slot.
Example 26 includes the apparatus of any of claims 22-25, wherein the slot is a first slot and the hinge includes a second slot, a second end of the rod including a second roller, the second roller slidingly received within the second slot.
Example 27 includes the apparatus of any of claims 22-26, wherein the hinge is a first hinge and further including a second hinge, the second heat sink pivotably coupled to the first hinge and the second hinge.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

1. An apparatus comprising:
a chassis;
a first heat sink associated with an electronic component in the chassis;
a second heat sink coupled to the first heat sink, the second heat sink spaced apart from the first heat sink in the chassis; and
damping material proximate to the second heat sink.

2. The apparatus of claim 1, wherein the damping material includes a first damping material extending along at least a portion of a first surface of the second heat sink.

3. The apparatus of claim 2, further including second damping material extending along at least a portion of a second surface of the second heat sink.

4. The apparatus of claim 1, wherein the damping material coupled to a wall of the chassis.

5. The apparatus of claim 4, wherein the second heat sink is coupled to the damping material.

6. The apparatus of claim 5, wherein the second heat sink is moveable relative to the chassis.

7. The apparatus of claim 1, wherein the damping material includes rubber or silicone.

8. An apparatus comprising:
a chassis;
a printed circuit board in the chassis;
an electronic component electrically coupled to the printed circuit board;
a first heat sink thermally coupled to the electronic component;
a second heat sink coupled to the first heat sink, the second heat sink spaced apart from the first heat sink, the second heat sink moveable relative to the chassis; and
a damper proximate to at least one of the first heat sink or the second heat sink in the chassis.

9. The apparatus of claim 8, wherein the damper extends along at least a portion of a first surface of the second heat sink.

10. The apparatus of claim 9, wherein the damper is one of (a) coupled to a wall of the chassis, a gap between the damper and the first surface of the second heat sink or (b) coupled to the first surface of the second heat sink, the gap between the damper and the wall of the chassis.

11. The apparatus of claim 9, wherein the damper is supported by a fastener, the fastener coupled to a wall of the chassis, the wall of the chassis proximate to the first surface of the second heat sink.

12. The apparatus of claim 8, wherein the damper is a first damper, the first damper extending in a first direction, and further including a second damper, the second damper extending along a second surface of the second heat sink in a second direction different than the first direction.

13. The apparatus of claim 8, wherein the electronic component is supported by a carrier, the damper coupled to the carrier.

14. The apparatus of claim 8, wherein the damper is carried by the first heat sink.

15.-21. (canceled)

22. An apparatus comprising:
a chassis;
a first heat sink associate with an electronic component in the chassis;
a second heat sink coupled to the first heat sink, the second heat sink spaced apart from the first heat sink in the chassis; and
a hinge coupled to a wall of the chassis, the second heat sink pivotably coupled to the hinge.

23. The apparatus of claim 22, further including a damper proximate to the second heat sink.

24. The apparatus of claim 22, wherein the second heat sink is pivotably coupled to the hinge via a rod.

25. The apparatus of claim 24, further including a slot in one of a surface of the second heat sink or a surface coupled to the second heat sink, a first end of the rod including a first roller, the first roller slidingly received within the slot.

26. The apparatus of claim 25, wherein the slot is a first slot and the hinge includes a second slot, a second end of the rod including a second roller, the second roller slidingly received within the second slot.

27. The apparatus of claim 22, wherein the hinge is a first hinge and further including a second hinge, the second heat sink pivotably coupled to the first hinge and the second hinge.
